(19) United States
(12) Patent Application Publication
(10) Pub. No.: US 2026/0191088 A1
(43) Pub. Date: Jul. 2, 2026

(54) SEMICONDUCTOR DEVICE INCLUDING NARROW GAP UNDERFILL MATERIAL

(71) Applicant: Sandisk Technologies, Inc., Milpitas, CA (US)

(72) Inventors: Nagesh Vodrahalli, Los Altos, CA (US); Chih Yang Li, Menlo Park, CA (US); Mutharasu Devarajan, Milpitas, CA (US)

(73) Assignee: Sandisk Technologies, Inc., Milpitas, CA (US)

(21) Appl. No.: 19/005,691

(22) Filed: Dec. 30, 2024

(51) Int. Cl. H01L 23/00; H01L 23/29; H01L 23/31; H01L 25/065; H10B 80/00

(52) U.S. Cl. CPC H10W 74/47; H10B 80/00; H10W 72/01323; H10W 72/01361; H10W 72/0198; H10W 72/248; H10W 72/252; H10W 72/321; H10W 72/354; H10W 72/921; H10W 72/9445; H10W 72/952; H10W 74/111; H10W 74/15; H10W 90/00; H10W 90/297; H10W 90/722; H10W 90/732

(57) ABSTRACT

A semiconductor device includes a number of stacked semiconductor dies and a partial, controlled amount of underfill material between each semiconductor die. The underfill material fills a central portion of the space between adjacent semiconductor dies, leaving an edge gap in the space around the underfill material. After the die stack has been completed, the stack may be encapsulated in mold compound. In addition to covering the surfaces of the die stack, the mold compound fills the edge gap so that all spaces between dies are filled.

### BACKGROUND

The strong growth in demand for portable consumer electronics is driving the need for high-capacity storage devices. Non-volatile semiconductor memory devices, such as flash memory storage cards, are widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs, cellular telephones and solid state drives (SSDs).

Recently, ultra high-density memory devices have been proposed using a 3D stacked memory structure having strings of memory cells formed into layers. One such storage device is sometimes referred to as a Bit Cost Scalable (BiCS) architecture. BiCS and other NAND memory devices are fabricated in a wafer which includes the memory device layer formed in a substrate base, such as silicon. The wafer is diced into individual semiconductor dies, which are then stacked, electrically connected and encapsulated to form a competed semiconductor memory package.

Microbumps on the bottom and/or top surface of the dies are used to bond the dies in the stack together, but provide a small space between the dies. It is important to fill this space to prevent environmental contaminants, such as moisture, from degrading device reliability. Filling the space between dies with a thermally conductive material is further critical for proper heat conduction away from the semiconductor device.

In conventional manufacturing processes, mold compound is used during encapsulation process to not only encapsulate the semiconductor device but to also fill the spaces between dies. However, present day devices have many microbumps to speed data transfer to and from the device. It is also desirable to minimize the gap height to minimize the overall thickness of the semiconductor package. These two factors make it difficult to fill the space between dies. Either voids are left within the space, or the encapsulation pressure needs to be set higher, risking damage to the semiconductor dies.

To address this challenge, underfill materials have been developed and applied to fill the space between dies. These materials are designed to flow into tight spaces and provide the necessary mechanical support and thermal conductivity. However, conventional underfill materials suffer from several drawbacks, including material bleeding beyond the edges of the package during application. This bleeding creates stresses and increases the risk of cracking during subsequent package assembly steps, compromising both yield and long-term reliability.

### DESCRIPTION OF THE DRAWINGS

FIG. 1 is a flowchart for forming a semiconductor die according to embodiments of the present technology.

FIG. 2 is a top view of a semiconductor wafer, and a semiconductor die therefrom, according to embodiments of the present technology.

FIGS. 3-5 are cross-sectional edge views of a semiconductor die from the wafer at various stages of fabrication according to embodiments of the present technology.

FIG. 6 is a flowchart for forming a semiconductor device according to embodiments of the present technology.

FIG. 7 is a cross-sectional edge view of a first, base semiconductor die mounted on a carrier according to embodiments of the present technology.

FIG. 8 is a cross-sectional edge view of a controlled layer of underfill applied to the surface of the base semiconductor die according to embodiments of the present technology.

FIG. 9 is a cross-sectional edge view of a second semiconductor die mounted on the base semiconductor die with a controlled layer of underfill in the space between the base and second semiconductor dies according to embodiments of the present technology.

FIG. 10 is a cross-sectional top view of a pair of stacked semiconductor dies including underfill material therebetween according to embodiments of the present technology.

FIG. 11 is a cross-sectional top view of a pair of stacked semiconductor dies including underfill material therebetween according to alternative embodiments of the present technology.

FIG. 12 is a cross-sectional edge view of a stack of semiconductor dies with controlled layers of underfill in the spaces between the semiconductor dies according to embodiments of the present technology.

FIG. 13 is a cross-sectional view of the stack of semiconductor dies encapsulated in mold compound according to embodiments of the present technology.

FIG. 14 is a cross-sectional edge view of the encapsulated stack of semiconductor dies with the temporary carrier layer removed, including an enlarged view of a section of the die stack, according to embodiments of the present technology.

FIG. 15 is a cross-sectional top view of a space between a pair of adjacent dies in the die stack filled with underfill material and mold compound according to embodiments of the present technology.

### DETAILED DESCRIPTION

The present technology will now be described with reference to the figures, which in embodiments, relate to a semiconductor device including a number of stacked semiconductor dies and a partial, controlled amount of underfill material between each semiconductor die. During assembly, a pair of adjacent dies are pressed together to bond their electrical connectors and the underfill material is flattened in a central portion of the space between adjacent semiconductor dies, leaving an edge gap in the space around the underfill material.

After the die stack has been completed, the stack may be encapsulated in mold compound. In addition to covering the surfaces of the die stack, the mold compound fills the edge gap so that all spaces between dies are filled. The underfill material may be the same used as the mold compound, or another material with similar thermal and thermal expansion properties.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom,” “upper” and “lower” and “vertical” and “horizontal,” and forms thereof, as may be used herein are by way of example and illustrative purposes only, and are not meant to limit the description of the technology inasmuch as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is ±0.15 mm, or alternatively, ±2.5% of a given dimension.

For purposes of this disclosure, a physical or electrical connection may be a direct connection or an indirect connection (e.g., via one or more other parts). In some cases, when a first element is referred to as being connected, affixed, mounted or coupled to a second element (either physically or electrically), the first and second elements may be directly connected, affixed, mounted or coupled to each other or indirectly connected, affixed, mounted or coupled to each other (either physically or electrically). When a first element is referred to as being directly connected, affixed, mounted or coupled to a second element, then there are no intervening elements between the first and second elements (other than possibly an adhesive or melted metal used to connect, affix, mount or couple the first and second elements).

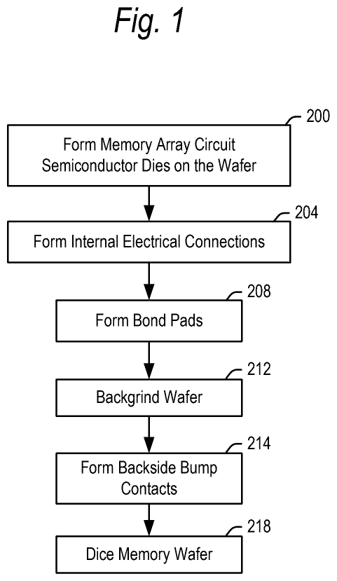

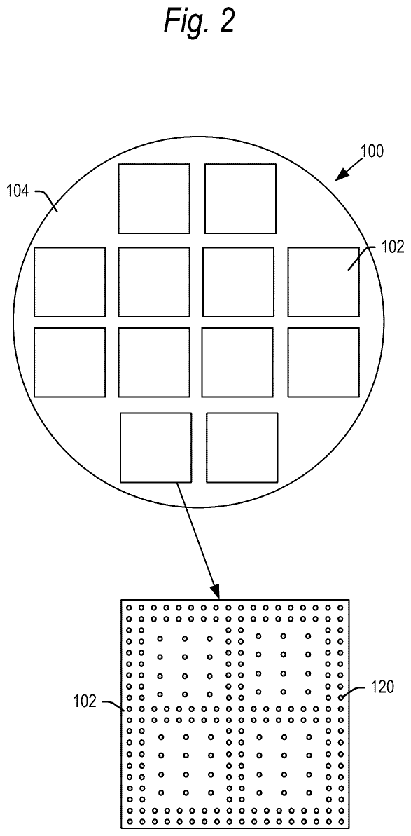

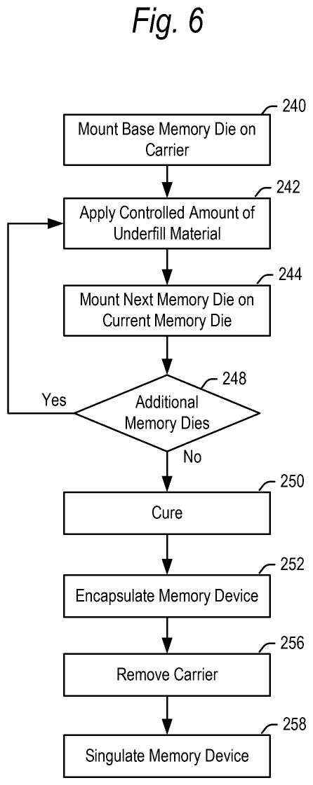

An embodiment of the present technology will now be explained with reference to the flowcharts of FIGS. 1 and 6, and the views of FIGS. 2-5 and 7-15. In step 200, a semiconductor wafer 100 may be processed into a number of semiconductor dies 102 as shown in FIG. 2. The semiconductor wafer 100 may start as an ingot of wafer material which may be monocrystalline silicon grown according to either a Czochralski (CZ) or floating zone (FZ) process. However, wafer 100 may be formed of other materials and by other processes in further embodiments.

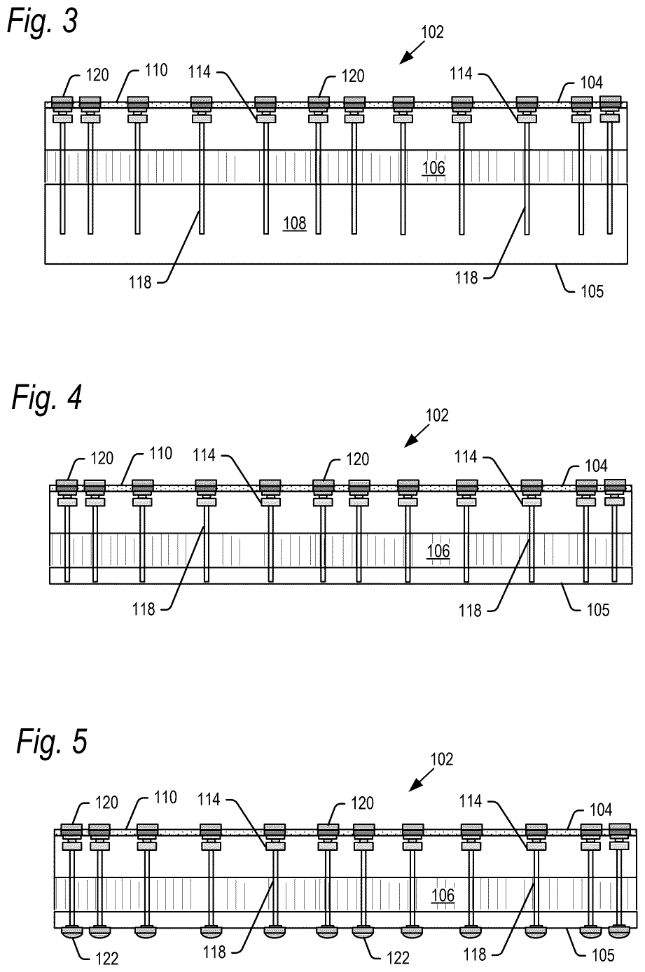

The semiconductor wafer 100 may be cut from the ingot and polished on both the first major planar surface 104, and second major planar surface 105 (FIG. 3) opposite surface 104, to provide smooth surfaces. The first major surface 104 may undergo various processing steps to divide the wafer 100 into the respective semiconductor dies 102, and to form integrated circuits of the respective semiconductor dies 102 on and/or in the first major surface 104. Surface 104 may also be referred to herein as the active surface of the die 102 and wafer 100.

In step 200, the semiconductor die 102 may be processed in embodiments to include integrated circuit memory cell array 106 formed in a dielectric substrate 108 as shown in the cross-sectional edge view of FIG. 3. FIG. 3 shows a single semiconductor die 102 from wafer 100. The substrate 108 may for example be or include silicon, such as silicon dioxide, but may be or include other materials in further embodiments. A passivation layer 110 may be formed on top of surface of the dies 102. The passivation layer 110 may for example be silicon dioxide, but may be formed of other materials in further embodiments. Such additional materials may include silicon nitride, silicon carbon nitride or others.

The memory cell array 106 may be configured to include multiple memory elements in which each element is individually accessible. By way of non-limiting example, memory cell array 106 may be a flash memory system in a NAND configuration (NAND memory) that contains memory elements connected in series. A NAND string is an example of a set of series-connected transistors comprising memory cells and select gate transistors. The memory cell array 106 may be configured so that the array is composed of multiple strings of memory in which a string is composed of multiple memory elements sharing a single bit line and accessed as a group. Alternatively, memory elements of memory cell array 106 may be configured so that each element is individually accessible, e.g., a NOR memory array. NAND and NOR memory configurations are exemplary, and memory elements may be otherwise configured.

The memory cell array 106 can be two-dimensional (2D), or three-dimensional (3D) including so-called BiCS memory arrays. A 3D memory array is arranged so that memory elements occupy multiple planes or multiple memory device levels, thereby forming a structure in three dimensions (i.e., in the x, y and z directions, where the z direction is substantially perpendicular, and the x and y directions are substantially parallel, to the major planar surface 104 of the semiconductor die 102). It is understood that the memory cell array 106 may have other configurations in further embodiments. Moreover, the type of memory die used is not critical to the present technology, and it is further understood that die 102 may be other types of semiconductor dies in further embodiments, including for example DRAM, SRAM and other types of volatile memories.

After or during formation of the memory cell array 106, internal electrical connections may be formed within the semiconductor die 102 in step 204. The internal electrical connections may include multiple layers of metal interconnects 114 and vias 118 formed sequentially above the memory cell array 106. As is known in the art, the metal interconnects 114 and vias 118 may be formed a layer at a time above the memory cell array 106 using photolithographic and thin-film deposition processes. The photolithographic processes may include for example pattern definition, plasma, chemical or dry etching and polishing. The thin-film deposition processes may include for example sputtering and/or chemical vapor deposition. The metal interconnects 114 may be formed of a variety of electrically conductive metals including for example copper and copper alloys as is known in the art.

The vias 118 may be formed by etching holes through the wafer 100. The holes may then be lined with a barrier against metal diffusion and to provide insulation of the metal conductor from silicon which may be conductive depending on the dopant level. The barrier layer may in turn be lined with a seed layer, and the seed layer may be plated with an electrical conductor such as copper, although other suitable materials such as aluminum, tin, nickel, gold, tungsten, doped polysilicon, and alloys or combinations thereof may be used.

In step 208, bond pads 120 may be formed on the major planar surface 104 of the semiconductor dies 102 as shown in FIGS. 2 and 3. The memory array circuits 106 may be electrically connected to the bond pads 120 by the metal interconnects 114 and vias 118. The number and position of metal interconnects 114, vias 118 and bond pads 120 shown in the figures is by way of example only, and may vary in further embodiments. For example, each die 102 may include more metal interconnects 114, vias 118 and bond pads 120 than are shown in further embodiments, and may include various other patterns of bond pads 120.

The bond pads 120 may be formed for example by coating a photoresist mask layer over the passivation layer 110 with openings in the mask layer aligned over the vias 118. Thereafter, one or more metal layers including the bond pads and possibly a liner layer may be deposited in the mask layer openings. The bond pads 120 may for example be formed of a metal such as copper, nickel or solder alloys. In embodiments, the bond pads 120 may be about 10 μm to 40 μm, square or rectangle, and spaced from each other with a pitch of 20 μm to 50 μm. It is understood that the size of bond pads 120 and the pitch between bond pads 120 may be larger or smaller than that in further embodiments.

Once the integrated circuits and metal interconnects have been fabricated, the wafer may be thinned, for example from 760 μm (FIG. 3) to a final thickness (FIG. 4). The final thickness may for example be between 10 μm and 50 μm, such as for example 25 μm, but the final thickness of wafer 100 may be thinner or thicker than that in further embodiments. The wafer 100 may be thinned in a traditional backgrind process in step 212 to thin the substrate layer 108.

FIG. 5 is a cross-sectional edge view of a finished semiconductor die 102 on wafer 100. The backgrind step 212 exposes vias 118 at the back (inactive) major planar surface 105. In step 214, a pattern of bump contacts 122 may then be formed on vias 118 at the inactive surface 105. In embodiments, the active surface 104 of wafer 100 may be supported on a dicing tape. The bump contacts 122 may then be formed for example by coating a photoresist mask layer over the inactive surface with openings in the mask layer over the vias 118. Thereafter, a metal such as copper, nickel or solder alloys may be plated into the mask openings to form the bump contacts 122 in the desired pattern. The bump contacts 122 may match the pattern and approximate size of the bond pads 120 in the active major planar surface 104.

An advantage of the embodiment shown in FIG. 5 is that the memory dies 102 may be stacked on each other as explained below in a chip scale package, meaning a package substrate may be omitted, and the footprint of the finished semiconductor device may be the footprint of the memory die stack alone. This is made possible by the vias 118 which together extend entirely through each memory die from the top surface 104 to the bottom surface 105. These vias 118 form through-silicon vias (TSVs).

The TSVs allow individual memory dies 102 to be stacked directly atop each other, with the bond pads 120 of a lower memory die being coupled directly to the bump contacts 122 of the next higher memory die. An advantage of using TSVs is that the memory modules are electrically connected without having to use wire bonds, and without having to offset step each memory die to make room for the wire bonds, thus decreasing the footprint of the finished semiconductor device.

Although several of the figures show an individual semiconductor die 102 for simplicity, at the stage of fabrication described thus far, the die 102 is still part of wafer 100. With the wafer supported on the dicing tape and after formation of the bump contacts 122, the wafer 100 may be diced to form individual semiconductor dies 102 in a step 218. The wafer 100 may be diced into individual memory dies 102 using for example stealth laser dicing. Saw blades and other traditional methods may be used in further embodiments. After dicing, the dicing tape may be spread apart to facilitate picking of the memory dies 102 from the dicing tape by a pick and place robot (not shown).

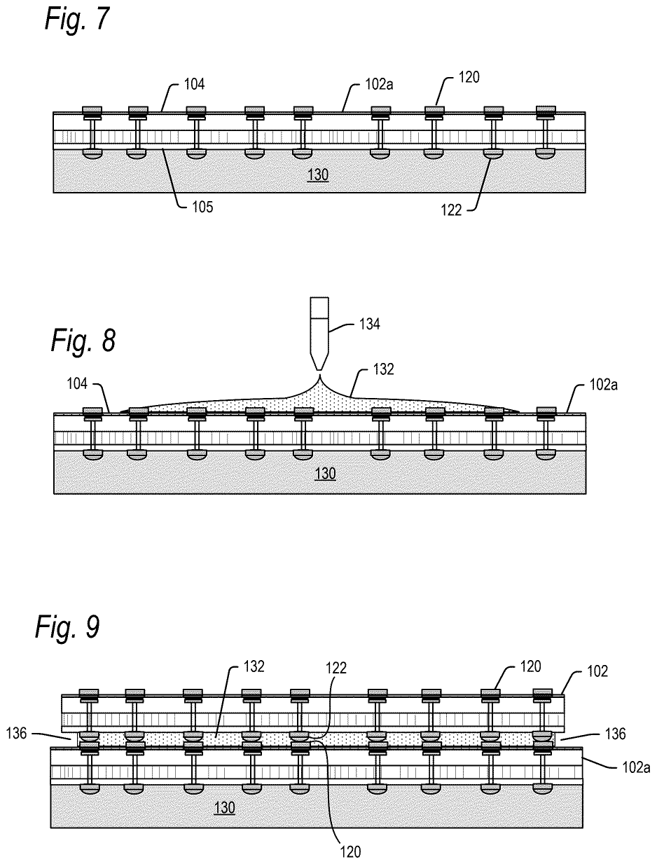

Once dies 102 are completed, the dies may be mounted into a semiconductor device including a novel underfill according to the present technology, which will now be explained with reference to the flowchart of FIG. 6 and the views of FIGS. 7-15. In step 240, a base memory die 102a may be mounted on a temporary carrier 130 as shown in the cross-sectional edge view of FIG. 7. An upper surface of the temporary carrier 130 may have a film in which the bump contacts 122 are burried so that the inactive surface 105 of the memory die 102a rests flush against the temporary carrier 130. The film also serves to hold the die 102a on the temporary carrier.

In embodiments, the memory die 102a may have the same pattern of contact pads 120 and bond contacts 122 as in the memory dies 102 described above. However, the memory die 102a may have a slightly larger footprint than dies 102 to provide a base for the molding compound as described below. The memory dies 102a may come from a different wafer than memory dies 102, with all dies 102a diced from the wafer with a slightly larger footprint than the dies 102 from wafer 100. In further embodiments, the die 102a may be omitted, and a memory die 102 as described above may be used as the base die affixed directly to the temporary carrier 130.

In step 242, a controlled amount of underfill material 132 may be dispensed onto the active surface 104 of die 102a as shown in the cross-sectional edge view of FIG. 8. The underfill material 132 may be dispensed as an a-stage liquid from a dispenser 134. In embodiments, the underfill material 132 may be a liquid curable to a solid, and may be chosen based on its mechanical, thermal, chemical and electrical properties. In embodiments, the underfill material 132 may be a dielectric material and may be formed of an epoxy resin such as for example Bisphenol A epoxy resin, a cyclic aliphatic epoxy resin, a Novolac epoxy resin and/or any of the materials described below for the mold compound 142. Other dielectric epoxy resins and other materials are possible.

The dielectric epoxy resin may include various fillers, including for example thermally conductive fillers such as aluminum nitride, boron nitride, silicon carbide, diamond nanoparticles and other materials. The epoxy resin may further include moisture-resistant fillers and curing agents and accelerators. One possible example of an underfill material 132 for use with the present technology is Loctite UF series underfill by Henkel USA, having offices in Stamford, CT. The underfill material 132 may be other types of underfill material from other manufacturers.

In accordance with aspects of the present technology, a discrete, controlled amount of underfill material 132 is applied from dispenser 134. The amount dispensed depends on a variety of factors including for example the final spacing between adjacent semiconductor dies and the footprint of the semiconductor dies. However, in embodiments, the amount of underfill material 132 dispensed is controlled such that, once sandwiched between adjacent semiconductor dies, the underfill material 132 covers from 60% to 95% of the space between the adjacent semiconductor dies, such as for example, 75% to 95% of the space between the semiconductor dies.

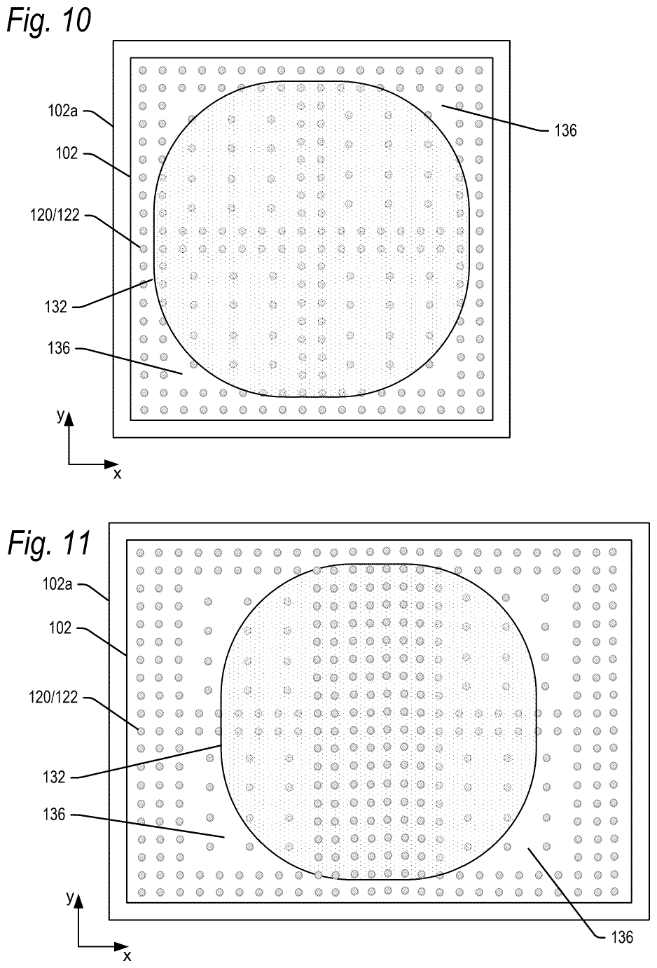

Thus, as shown in the cross-sectional edge and top views of FIGS. 9 and 10, a semiconductor die 102 may be mounted on top of the base semiconductor die 102a in a step 244. Once dies 102 and 102a are bonded together as explained below, the underfill material 132 may fill for example from 60% to 95% of the footprint of semiconductor die 102. The underfill material 132 is applied onto a central portion of the base die 102a (centered along both the x-axis and y-axis of semiconductor dies 102a and 102) so that the underfill material 132 fills an entirety of the central portion of the space between dies 102a and 102. The underfill material does not reach any edge of the space between dies 102a and 102, thus creating an edge gap 136 in the space between dies 102a and 102 around the periphery of underfill material 132 that is empty and devoid of underfill material 132.

In the embodiment of FIG. 10, the dies 102a and 102 may have a square footprint, so that the edge gap 136 is the same around the four sides of the underfill material 132. However, the dies 102a, 102 need not be square in further embodiments. FIG. 11 shows an example where the dies are rectangular, being longer along the x-axis than along the y-axis. In this example, the underfill material will have a larger edge gap 136 along the x-axis than along the y-axis. As shown in both FIGS. 10 and 11, some of the bond pads/bump contact pairs may be in the edge gap 136, outside of the underfill material 123.

Referring to FIG. 9, the dies 102a and 102 may be pressed together until the bump contacts 122 of die 102 rest against the bond pads 120 of die 102a through the underfill material 132. As indicated above, the pattern of bump contacts 122 may match the pattern of bond pads 120. The bump contacts 122 may be bonded to the bond pads 120 by various methods, including for example Cu-Cu bonding to electrically and physically couple the dies 102a and 102. The process of Cu-Cu bonding is known, but in general, the bond pads 120 in die 102a and the bump contacts 122 in die 102 are controlled to be highly planar in their respective dies and formed in a highly controlled environment largely devoid of ambient particulates that might otherwise settle on a bond pad 120 and/or bump contact 122 and prevent a close bond. The bond pads and bump contacts may for example be cleaned by CMP or particle bombardment techniques to remove any oxide layer and particulates on the surfaces of the bond pads. Once aligned, the bond pads 120 and bump contacts 122 may be pressed against each other to form a mutual bond based on surface tension. Such bonds may be formed at room temperature, though heat may also be applied. Cu atoms of joined pads 120 and contacts 122 diffuse across the boundary to ensure a secure bond.

The bonds between the bond pads 120 and bump contacts 122 define a height of the space between dies 102 and 102a. Other wafer-to-wafer bonding techniques are possible. Such further techniques include various dielectric-to-dielectric bonding techniques including oxide-to-oxide bonding, silicon-to-silicon bonding, and silicon-to-silicon dioxide bonding. In addition to the bonds between the bond pads 120 and bump contacts 122, the underfill material 132 will help bond the dies together, especially after the underfill material is cured as explained below.

In examples, bonding of the bump contacts 122 of one die to the bond pads 120 of a next lower die may create a spacing between the dies of between 5 μm and 25 μm, such as for example between 10 μm and 20 μm, or between 12 μm and 15 μm. The space between adjacent dies may be larger or smaller than these ranges in further embodiments. As noted, interior portions of these spaces are filled with the underfill material 132, leaving an edge gap 136 around the periphery of the underfill material 132.

In step 248, additional dies 102 may be added to the die stack. When adding each new die 102, a controlled amount of underfill material 132 is first dispensed onto an upper surface of the top die as explained above, and then the next die is added to the stack and bonded as described above. The space between each die 102, 102a in the stack may have the same amount of underfill material 132. However, it is possible that the spaces between adjacent dies have differing amounts of underfill material 132 in further embodiments.

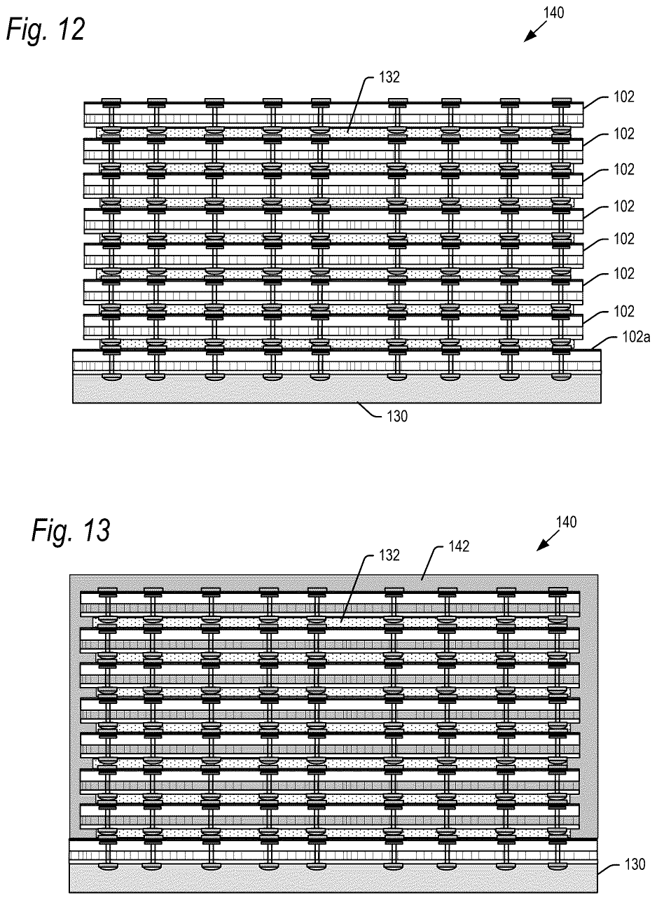

FIG. 12 is a cross-sectional edge view of a die stack 140 including 8 dies 102 (including base die 102a). Each die 102 has its bump contacts 122 bonded to the bond pads 120 of the next lower die. The spaces created by the bond pad / bump contact bonding are each filled with underfill material 132. While the example of FIG. 8 includes 8 memory dies 102/102a, the stack 140 may have other numbers of dies, including for example 2, 4, 16, 32 and 64 dies. There may be other numbers of dies in further embodiments.

After the dies 102, 102a have been added to the die stack 140, the underfill material 132 between each die pair may be cured to a solid in step 250. While the curing process may be performed under a variety of time and temperature conditions, in one example, the underfill material 132 may be heated to a temperature of between 120° C. and 200° C. for a period of 30 to 90 minutes. The temperature may be ramped up slowly (e.g., 2° C.-5° C. per minute) to minimize thermal stresses on the memory dies 102, 102a.

After the curing step 250, the die stack 140 may be encapsulated in a mold compound 142 in step 252 and as shown in FIG. 13. Mold compound 142 may include for example solid epoxy resin, Phenol resin, fused silica, crystalline silica, carbon black, metal hydroxide and/or any of the materials described above for the underfill material 132. Such mold compounds are available for example from Sumitomo Corp. and Nitto-Denko Corp., both having headquarters in Japan. Other mold compounds from other manufacturers are contemplated. The mold compound may be applied by a FFT (Flow Free Thin) process or by other known processes, including by transfer molding or injection molding techniques. The mold compound 142 may be applied flush with the edges of base die 102a to have the same footprint of die 102a. Alternatively, the mold compound 142 may have a larger footprint than base die 102a to fully encapsulate edges of the base die 102a.

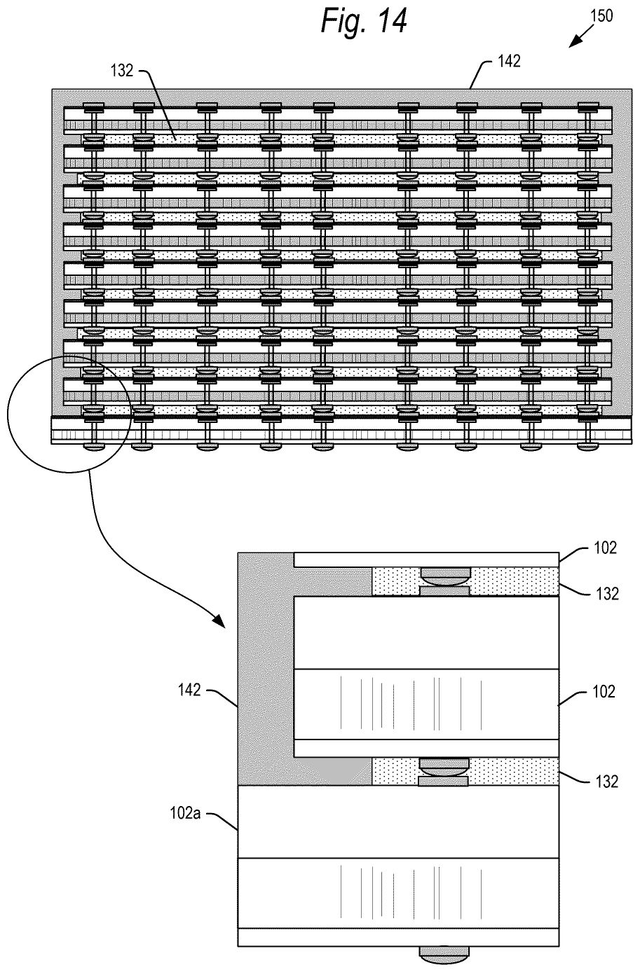

After the encapsulation step 252, the temporary carrier 130 may be removed in step 256 and as shown in FIG. 14. The temporary carrier 130 may be removed for example by heating the film layer between the carrier and the base die 102a. After removal of the temporary carrier 130, the bump contacts 122 on a bottom surface of the base die 102a may be cleaned to remove any particulates and traces of the film layer.

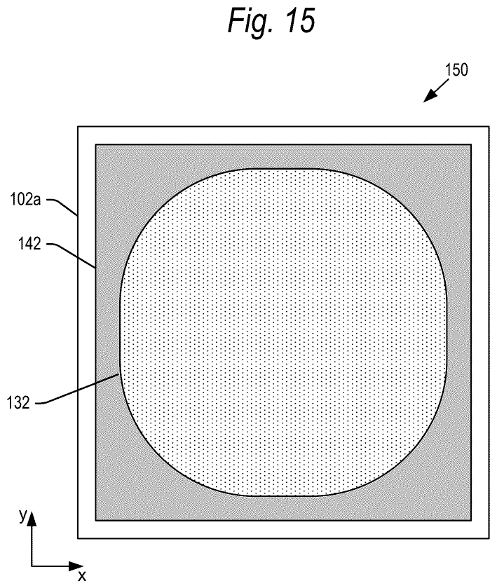

In order to take advantage of economies of scale, multiple die stacks 140 may be formed simultaneously and encapsulated together in a block on the temporary carrier 130, either in a single line or a two-dimensional array. In step 258, die stacks 140 may be singulated from each other to form finished semiconductor devices 150 as shown in FIGS. 14 and 15. The semiconductor devices 150 may be singulated by any of a variety of cutting methods including sawing, water jet cutting, laser cutting, water guided laser cutting, dry media cutting, and diamond coating wire cutting. While straight line cuts will define generally square or rectangular shaped semiconductor devices 150, it is understood that semiconductor device 150 may have shapes other than square and rectangular in further embodiments of the present technology.

As best seen in the enlarged sectional view of FIG. 14 and the cross-sectional top view of FIG. 15, in addition to encapsulating the dies 102, 102a, the mold compound 142 seeps into and fills all of the edge gaps 136 under the pressure of the encapsulation process. The mold compound 142 fills all edge gaps 136 and lies flush against the underfill material 132. Thus, the underfill material 132 and mold compound 142 together entirely fill the spaces between the semiconductor dies 102, 102a. In embodiments, the underfill material 132 may be the same material as the mold compound 142. They may be different materials in further embodiments, but have similar properties including similar coefficients of thermal expansion.

In summary, embodiments of the present technology relate to A semiconductor device, comprising: a plurality of semiconductor dies stacked on each other, a space being defined between a pair of adjacent semiconductor dies of the plurality of semiconductor dies; an underfill material partially filling the space between the pair of adjacent semiconductor dies; and a mold compound encapsulating the semiconductor device and partially filling the space between the pair of adjacent semiconductor dies; wherein the underfill material and the mold compound together entirely fill the space between the pair of adjacent semiconductor dies.

In another example, the present technology relates to a semiconductor device, comprising: a plurality of semiconductor dies stacked on each other, a space being defined between a pair of adjacent semiconductor dies of the plurality of semiconductor dies; an underfill material partially filling a central portion of the space between the pair of adjacent semiconductor dies, the underfill material leaving an edge gap around a periphery of the underfill material in the space that is empty; and a mold compound encapsulating the semiconductor device and filling the edge gap; wherein the underfill material and the mold compound together entirely fill the space between the pair of adjacent semiconductor dies.

In a further example, the present technology relates to a semiconductor device, comprising: a plurality of semiconductor dies stacked on each other, a space being defined between a pair of adjacent semiconductor dies of the plurality of semiconductor dies; filler means, comprising an underfill material surrounded by a mold compound, for entirely filling the space without bleeding outside of a footprint of one of the semiconductor dies of the pair of semiconductor dies.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed is:

1. A semiconductor device, comprising:
a plurality of semiconductor dies stacked on each other, a space being defined between a pair of adjacent semiconductor dies of the plurality of semiconductor dies;
an underfill material partially filling the space between the pair of adjacent semiconductor dies; and
a mold compound encapsulating the semiconductor device and partially filling the space between the pair of adjacent semiconductor dies;
wherein the underfill material and the mold compound together entirely fill the space between the pair of adjacent semiconductor dies.

2. The semiconductor device of claim 1, further comprising:
a first set of electrical connectors on a first surface of one of the dies of the pair of adjacent semiconductor dies, and
a second set of electrical connectors on a second surface of the other of the dies of the pair, the first set of electrical connectors bonded to the second set of electrical connectors to electrically and physically couple the pair of adjacent semiconductor dies.

3. The semiconductor device of claim 1, wherein the coupling of the first and second sets of electrical connectors define a height of the space between the pair of adjacent semiconductor dies.

4. The semiconductor device of claim 1, wherein the underfill material and molding compound have a matching coefficient of thermal expansion.

5. The semiconductor device of claim 1, wherein the underfill material and molding compound are made of the same material.

6. The semiconductor device of claim 1, wherein the underfill material comprises an epoxy resin.

7. The semiconductor device of claim 6, wherein the molding compound comprises an epoxy resin.

8. The semiconductor device of claim 6, wherein the underfill material comprises a thermally conductive filler.

9. The semiconductor device of claim 1, wherein the underfill material fills a central portion of the space and the molding compound fills an edge gap in the space surrounding the underfill material.

10. The semiconductor device of claim 1, wherein the underfill material fills between 60% and 95% of the spaces between the pair of adjacent semiconductor dies.

11. The semiconductor device of claim 1, wherein the underfill material fills between 75% and 95% of the space between the pair of adjacent semiconductor dies.

12. The semiconductor device of claim 1, wherein the plurality of semiconductor dies comprise flash memory dies.

13. The semiconductor device of claim 1, wherein the underfill material is cured before the molding compound.

14. A semiconductor device, comprising:
a plurality of semiconductor dies stacked on each other, a space being defined between a pair of adjacent semiconductor dies of the plurality of semiconductor dies;
an underfill material partially filling a central portion of the space between the pair of adjacent semiconductor dies, the underfill material leaving an edge gap around a periphery of the underfill material in the space that is empty; and
a mold compound encapsulating the semiconductor device and filling the edge gap;
wherein the underfill material and the mold compound together entirely fill the space between the pair of adjacent semiconductor dies.

15. The semiconductor device of claim 14, further comprising:
a first set of electrical connectors on a first surface of one of the dies of the pair of adjacent semiconductor dies, and
a second set of electrical connectors on a second surface of the other of the dies of the pair, the first set of electrical connectors bonded to the second set of electrical connectors to electrically and physically couple the pair of adjacent semiconductor dies;
wherein the coupling of the first and second sets of electrical connectors define a height of the space between the pair of adjacent semiconductor dies.

16. The semiconductor device of claim 14, wherein the underfill material and molding compound have a matching coefficient of thermal expansion.

17. The semiconductor device of claim 14, wherein the underfill material and mold compound comprise an epoxy resin.

18. The semiconductor device of claim 14, wherein the underfill material comprises a thermally conductive filler.

19. The semiconductor device of claim 14, wherein the underfill material fills between 60% and 95% of the spaces between the pair of adjacent semiconductor dies.

20. A semiconductor device, comprising:
a plurality of semiconductor dies stacked on each other, a space being defined between a pair of adjacent semiconductor dies of the plurality of semiconductor dies;
filler means, comprising an underfill material surrounded by a mold compound, for entirely filling the space without bleeding outside of a footprint of one of the semiconductor dies of the pair of semiconductor dies.
